(19) United States
(12) Patent Application Publication
(10) Pub. No.: US 2026/0239738 A1
(43) Pub. Date: Aug. 13, 2026

(54) SEMICONDUCTOR DEVICE AND METHOD FOR FORMING THE SAME

(71) Applicant: Taiwan Semiconductor Manufacturing Company, LTD., Hsinchu (TW)

(72) Inventor: Hung-Te Lin, Hsinchu (TW)

(21) Appl. No.: 19/047,850

(22) Filed: Feb. 7, 2025

(51) Int. Cl. H10D 86/00; H01L 21/265; H01L 21/762; H10D 30/01; H10D 30/65; H10D 62/17; H10D 86/01

(52) U.S. Cl. CPC H10D 86/201; H10D 62/292; H10D 86/01; H10P 30/204; H10P 30/209; H10P 30/21; H10P 90/1906; H10P 90/1908; H10W 10/014; H10W 10/061; H10W 10/17; H10W 10/181; H10D 30/0281; H10D 30/657

(57) ABSTRACT

Methods for forming bias-controlled silicon-on-insulator (SOI) regions are disclosed, along with such substrates and integrated circuits thereon. A trench is formed in a base substrate, and a pickup channel is formed therein. A buried dielectric layer is formed over the pickup channel, and a semiconducting substrate is formed over the buried dielectric layer. A central layer of the pickup channel extends through the buried dielectric layer and is electrically connected to the semiconducting substrate. Other integrated circuits can be formed on the base substrate as well. This results in flexible design layouts.

### BACKGROUND

Integrated circuits can be formed on silicon-on-insulator (SOI) substrates. The substrate is a layered semiconductor-insulator-semiconductor substrate, such as silicon-silicon dioxide-silicon substrate, rather than a bulk semiconductor substrate. Semiconductor devices constructed on the upper silicon layer are electrically isolated from the bulk silicon, which lowers parasitic capacitance, which improves power consumption. In addition, crosstalk arising from capacitive, inductive, and/or conductive coupling between separate devices on the same substrate can be reduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view showing two silicon-on-insulator (SOI) regions in a base substrate, in accordance with some embodiments of the present disclosure. FIG. 1B is a plan view of FIG. 1A. FIG. 1C is a Y-axis cross-sectional view through one SOI region. FIG. 1D is a plan view through line D-D of FIG. 1C. FIG. 1E is a plan view of a first embodiment through line E-E of FIG. 1C. FIG. 1F is a plan view of a second embodiment through line E-E of FIG. 1C.

FIGS. 2A-2C together form a flow chart illustrating a method for making a base substrate with one or more SOI regions, in accordance with some embodiments.

FIG. 3 is a Y-axis cross-sectional view showing the base substrate after isolation region(s) are formed and a first mask is applied.

FIG. 4 is a Y-axis cross-sectional view showing the base substrate after etching to form a trench in the base substrate.

FIG. 5 is a Y-axis cross-sectional view showing the base substrate after a second mask is applied.

FIG. 6 is a Y-axis cross-sectional view showing the base substrate doping with a first dopant type to form at least one pickup channel.

FIG. 7 is a Y-axis cross-sectional view showing an alternative variation in which an alternative second mask is used and ion implantation is performed to form the pickup channel. Here, the pickup channel also includes one or more contact regions on the upper surface of the base substrate.

FIG. 8 is a Y-axis cross-sectional view showing the base substrate after the first mask is applied again.

FIG. 9 is a Y-axis cross-sectional view showing the base substrate after epitaxy to form a first epitaxial layer upon the pickup channel.

FIG. 10 is a Y-axis cross-sectional view showing the base substrate after a third mask is applied. The third mask covers one or more central regions of the trench.

FIG. 11 is a Y-axis cross-sectional view showing the base substrate after doping a layer of the trench with a primary dopant.

FIG. 12 is a Y-axis cross-sectional view showing the base substrate after a fourth mask is applied.

FIG. 13 is a Y-axis cross-sectional view showing the base substrate after doping the central region(s) to form central layer(s) electrically connected to the pickup channel. Optionally, one or more contact regions can also be formed on the upper surface of the base substrate if desired.

FIG. 14 is a Y-axis cross-sectional view showing the base substrate after a fifth mask is applied and epitaxy is performed to form a second epitaxial layer upon the primary dopant-doped layer.

FIG. 15 is a Y-axis cross-sectional view showing the base substrate after a buried dielectric layer is formed from the primary dopant-doped layer by annealing.

FIG. 16 is a Y-axis cross-sectional view showing the base substrate after filling the trench to form a semiconducting substrate above the buried dielectric layer. The SOI region is thus formed in the base substrate.

FIG. 17 is a Y-axis cross-sectional view showing the base substrate after planarization of the semiconducting substrate.

FIG. 18A is a Y-axis cross-sectional view showing the two silicon-on-insulator (SOI) regions in the base substrate with transistors formed upon the semiconducting substrates of each SOI region, in accordance with some embodiments of the present disclosure. FIG. 18B is a plan view of one SOI region of FIG. 18A.

FIG. 19 is a flow chart illustrating a method for making one or more semiconductor devices in an SOI region, in accordance with some embodiments.

FIG. 20A is a Y-axis cross-sectional view showing another embodiment of an SOI region in the base substrate, in accordance with some embodiments of the present disclosure. Here, the SOI region includes an n-doped pickup channel and a p-doped pickup channel, and the semiconducting substrate of the SOI region includes an n-doped well and a p-doped well. FIG. 20B is a plan view through line B-B of FIG. 20A.

FIG. 21A and FIG. 21B together form a flow chart illustrating a method for making the SOI region of FIG. 20A, in accordance with some embodiments.

FIG. 22 is a Y-axis cross-sectional view showing the base substrate after etching to form a trench in the base substrate, and forming the n-doped pickup channel.

FIG. 23 is a Y-axis cross-sectional view showing the base substrate after forming the p-doped pickup channel.

FIG. 24 is a Y-axis cross-sectional view showing the base substrate after epitaxy to form a first epitaxial layer over the two pickup channels.

FIG. 25 is a Y-axis cross-sectional view showing the base substrate after a mask is applied that covers a central region over each pickup channel, and subsequent doping of a layer of the trench with a primary dopant.

FIG. 26 is a Y-axis cross-sectional view showing the base substrate after the central region over each pickup channel are similarly doped to form the central layer electrically connected to the pickup channel.

FIG. 27 is a Y-axis cross-sectional view showing the base substrate after epitaxy is performed to form a second epitaxial layer upon the primary dopant-doped layer.

FIG. 28 is a Y-axis cross-sectional view showing the base substrate after a buried dielectric layer is formed from the primary dopant-doped layer by annealing.

FIG. 29 is a Y-axis cross-sectional view showing the base substrate after filling the trench to form a semiconducting substrate above the buried dielectric layer. The central layers contact the semiconducting substrate.

FIG. 30 is a Y-axis cross-sectional view showing the base substrate after the portion of the semiconducting substrate above the n-doped pickup channel is doped to form an n-doped well, and the portion of the semiconducting substrate above the p-doped pickup channel is doped to form a p-doped well.

FIG. 31 is a Y-axis cross-sectional view after an isolation region is formed between the n-doped well and the p-doped well. Here, the isolation region does not extend into the buried dielectric layer.

FIG. 32 is a Y-axis cross-sectional view of an alternative embodiment where the isolation region passes through the buried dielectric layer and into the base substrate.

FIG. 33A is a plan view of another embodiment, where the SOI region includes a 2×2 array of alternating n-doped wells and p-doped wells.

FIG. 33B is a plan view of another embodiment, where the SOI region includes a 2×4 array of alternating n-doped wells and p-doped wells.

FIG. 34A is a Y-axis cross-sectional view of a base substrate that includes integrated circuits in two active regions of the base substrate, two non-bias-controlled SOI regions, and two bias-controlled SOI regions. FIG. 34B is a plan view through line B-B of FIG. 34A.

FIG. 35 is a flow chart illustrating a method for using a transistor in an bias-controlled SOI region, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure refers to “length” and “width”. These terms should not be construed as implying the length must have a greater value than the width.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure refers to temperatures for certain process steps. It is noted that these generally refer to the temperature at which the heat source (e.g. furnace) is set, and do not necessarily refer to the temperature which must be attained by the material being exposed to the heat.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” or “over” the substrate, even though they do not all directly contact the substrate. The term “directly” may be used to indicate two layers directly contact each other without any layers in between them. In addition, when referring to performing process steps upon the substrate or over the substrate, this should be construed as performing such steps to whatever layers may be present on the substrate as well, depending on the context.

The present disclosure relates to base substrates that include a silicon-on-insulator (SOI) region, and methods for making and using such base substrates. In the present disclosure, the SOI region includes a pickup channel underneath the insulator layer. The pickup channel permits the bias of the semiconducting layer above the insulator layer to be controlled in such bias-controlled SOI regions. Such substrates can also be produced in-house at a foundry and adapted for specific device needs. These SOI regions can also be combined with non-bias-controlled SOI regions, as well as integrated circuits formed directly in the base substrate. This permits flexible layout structures for different designs.

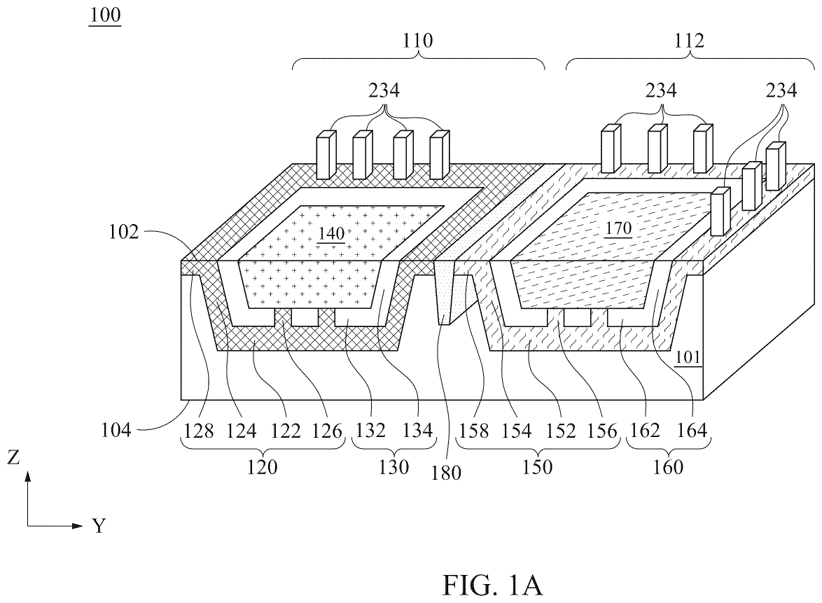

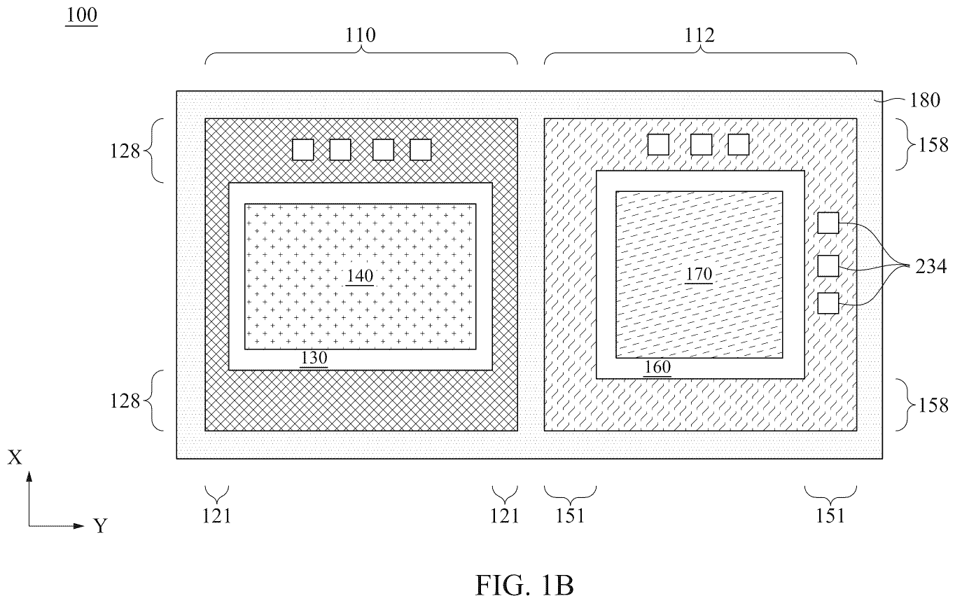

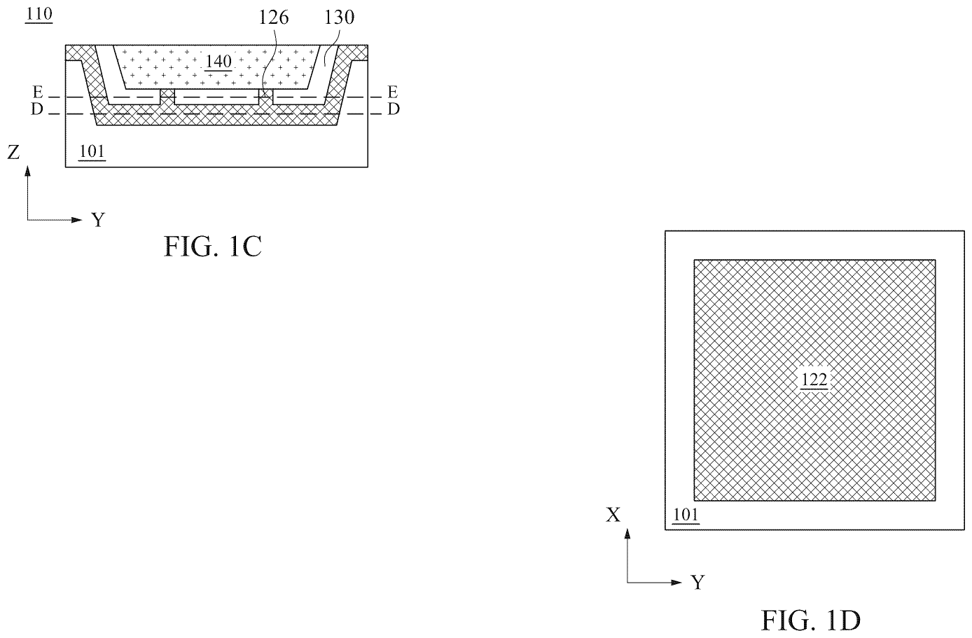

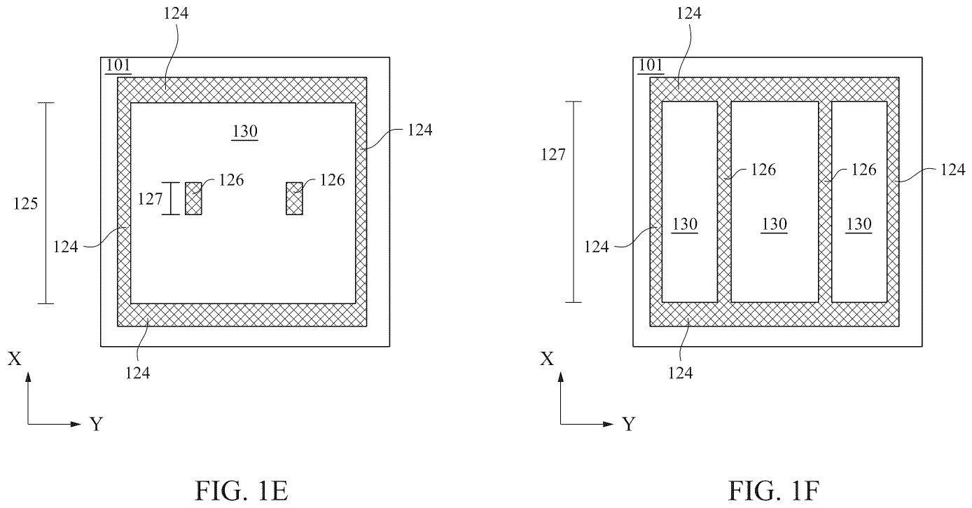

FIGS. 1A-1F are various views of a base substrate that includes two silicon-on-insulator (SOI) regions, according to some embodiments of the present disclosure. FIG. 1A is a perspective view. FIG. 1B is a plan view. FIG. 1C is a Y-axis cross-sectional view through one SOI region. FIG. 1D is a plan view through line D-D of FIG. 1C. FIG. 1E is a plan view of a first embodiment through line E-E of FIG. 1C. FIG. 1F is a plan view of a second embodiment through line E-E of FIG. 1C.

Referring first to FIGS. 1A-FIG. 1C, the base substrate 100 includes a bulk region 101. The base substrate also has a front side or upper surface 102, and has a back side or lower surface 104. Two bias-controlled SOI regions 110, 112 are illustrated on the front side of the base substrate. The two SOI regions are electrically isolated from each other by an isolation region 180.

The first SOI region includes one or more first pickup channels 120, a first buried dielectric layer 130, and a first semiconducting substrate 140. As illustrated here, the first pickup channel 120 is formed from a bottom layer 122, one or more sidewalls 124, one or more central layers 126, and optionally one or more contact regions 128, all of which are physically and electrically connected together. The first pickup channel is doped with a first dopant type (p-type or n-type). The bottom layer 122 is located within the base substrate. The sidewalls 124 extend from the bottom layer 122 to the upper surface 102 of the base substrate. The central layers 126 extend from the bottom layer 122 through the first buried dielectric layer 130 and are electrically connected to the first semiconducting substrate 140. The contact regions 128 are formed along the upper surface of the substrate and extend along the upper surface beyond the sidewalls. It is noted the contact regions are optional, and do not need to be present. The number of sidewalls and contact regions may vary depending on the perspective. For example, the first pickup channel could be described as having four trapezoidal sidewalls which are physically joined together along their edges, or as having one sidewall. In particular embodiments, the pickup channel may independently have one to four sidewalls and one to four contact regions.

The first buried dielectric layer 130 is located within the volume between the upper surface 102 of the base substrate and the first pickup channel 120. As illustrated here, the first buried dielectric layer 130 is formed from a bottom layer 132 in the X-Y plane and one or more sidewalls 134 that extend upwards in the Z-axis from the bottom layer to the upper surface 102 of the substrate. The first buried dielectric layer electrically isolates the first semiconducting substrate 140 from the base substrate 100. The first semiconducting substrate is also doped with the first dopant type, and may be referred to as a doped well. The bias of the first semiconducting substrate can be controlled using the first pickup channel. It is noted the dopant concentration in the first pickup channel and the dopant concentration in the first semiconducting substrate may have any desirable ratio.

The second SOI region includes one or more second pickup channels 150, a second buried dielectric layer 160, and a second semiconducting substrate 170. These structures may be described in the same manner as the first SOI region, except that the second pickup channel is doped with a second dopant type (n-type or p-type). The second pickup channel 150 is formed from a bottom layer 152, one or more sidewalls 154, one or more central layers 156, and optionally one or more contact regions 158. The second buried dielectric layer 160 is formed from a bottom layer 162 in the X-Y plane and one or more sidewalls 164 that extend upwards in the Z-axis from the bottom layer to the upper surface 102 of the substrate.

The first dopant type and the second dopant type are different from each other. If the first dopant type is an n-type dopant, then the second dopant type is a p-type dopant, or vice versa. As illustrated here, the first dopant type is n-type, and the second dopant type is p-type.

Four electrical contacts 234 are shown electrically contacting the first pickup channel 120 on one side of the first semiconducting substrate, whereas six electrical contacts 234 are shown electrically contacting the second pickup channel 150 on two sides of the second semiconducting substrate. Generally, any desired number of electrical contacts may be made to any desired location. The electrical contacts may electrically contact a sidewall (or a contact region, when present) of the pickup channel.

Referring more specifically to the plan view of FIG. 1B, the dimensions of the two SOI regions 110, 112 are independent of each other. As illustrated here, the first buried dielectric layer 130 and the first semiconducting substrate 140 have a rectangular shape while the second buried dielectric layer 160 and the second semiconducting substrate 170 have a square shape. Generally, the various layers may have any desired shape (in the plan view). In addition, the two contact regions 128 of the first SOI region running along the Y-axis have a different width from the two contact regions 121 running along the X-axis. In contrast, the widths of the four contact regions 151, 158 in the second SOI region are equal.

Referring now to FIGS. 1C-1E, the cross-sectional view of FIG. 1C shows the central layers 126 extending from the bottom layer 122 through the first buried dielectric layer 130 to the first semiconducting substrate 140. FIG. 1D shows the bottom layer 122 of the first pickup channel is solid, without any holes.

In one embodiment shown in FIG. 1E, the four sidewalls 124 of the first pickup channel are visible, and two central layers 126 are illustrated. In this embodiment, each central layer has a length 127 which is shorter than a length 125 of the sidewall. Each central layer 126 is surrounded by the first buried dielectric layer 130 and does not contact a sidewall.

In the alternative embodiment of FIG. 1F, the two central layers 126 have a length 127 which is about equal to the length 125 of the sidewall, and contact the opposite sidewalls. The first buried dielectric layer 130 can be described as being around each central layer 126. Generally, then, any number of central layers may be present, may have any desired dimensions, and may extend through the first buried dielectric layer in any desired location.

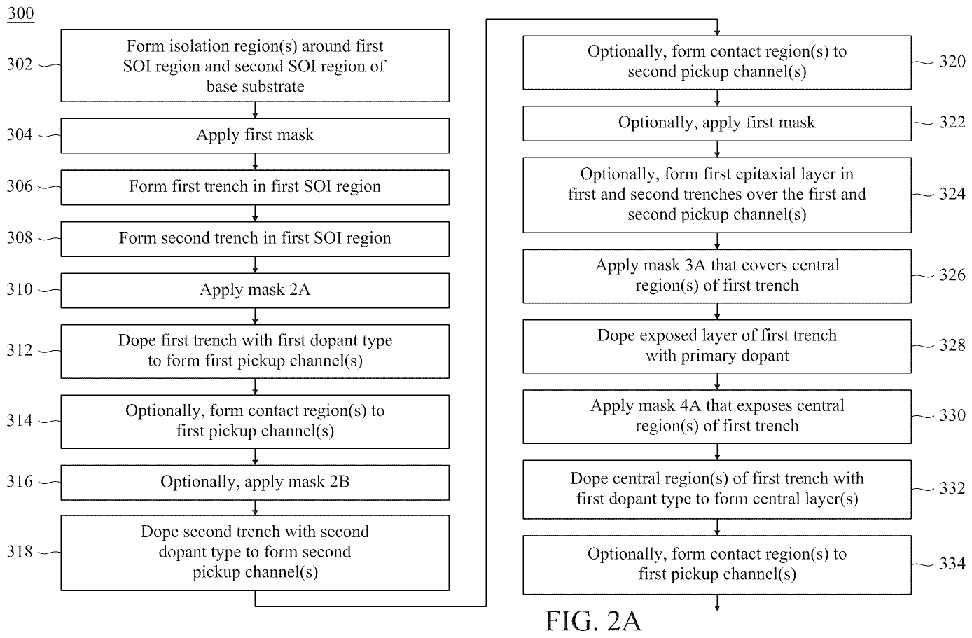

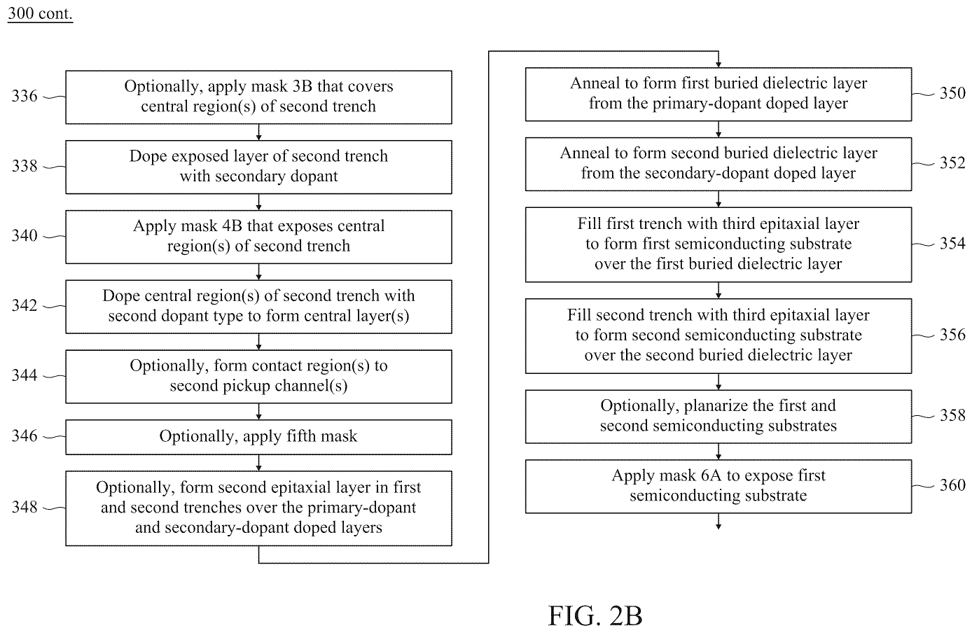

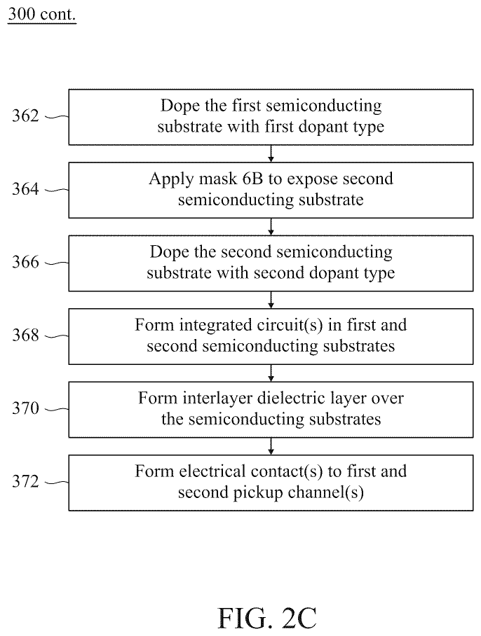

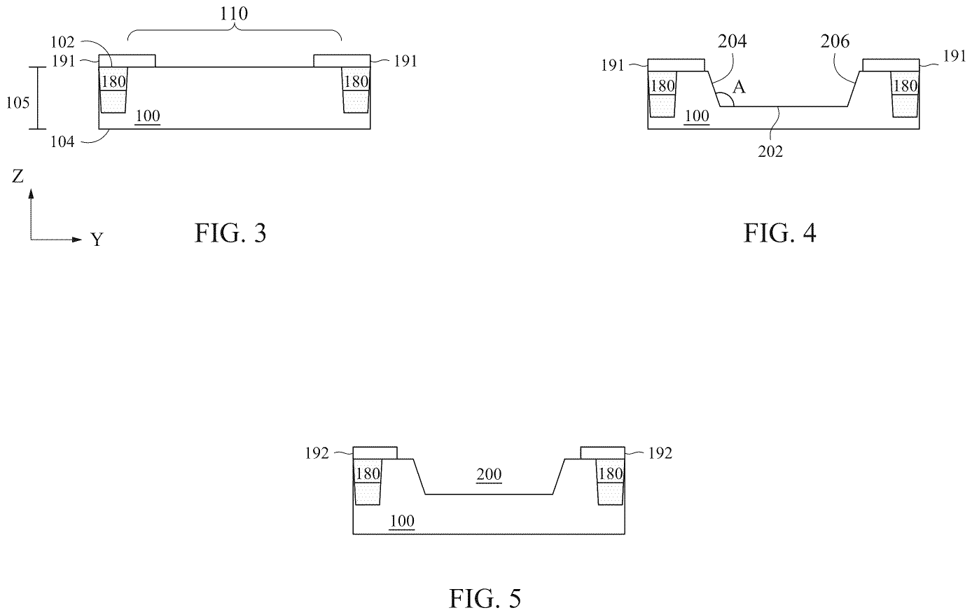

FIGS. 2A-2C together form a flow chart illustrating a method 300 for forming an SOI region in a base substrate, in accordance with some embodiments. Some steps of the method are also illustrated in FIGS. 3-17. These figures provide different views for better understanding. It is noted that in these figures, only Y-axis cross-sectional views are illustrated, and it may be assumed that the X-axis cross-sectional views are similar to the Y-axis views. While the method steps are discussed below in terms of forming a single pickup channel in a single SOI region, such discussion should also be broadly construed as applying to the formation of multiple pickup channels in a single SOI region, or the concurrent formation of multiple SOI regions. Other structures may also be concurrently formed. It is noted that not all steps described in the flow chart are required, and not all method steps are described in the flow chart.

Referring first to FIG. 3, the method begins with a base substrate 100. The base substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SIC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The base substrate 100 has an upper surface 102 and a lower surface 104, and has a thickness 105 between these two surfaces.

Initially, as indicated in step 302 of FIG. 2A and as illustrated in FIG. 3, one or more isolation region(s) 180 are formed within the base substrate 100 to define the first SOI region 110, as well as the second SOI region. These may be considered to be shallow trench isolation (STI) regions. As previously mentioned, when considered in three dimensions, the two STI regions in FIG. 3 may be linked to each other and could be considered as one isolation region (see for example FIG. 1B).

The isolation regions are formed by patterning the substrate, etching trenches, and filling the trenches with a dielectric material. The dielectric material in the isolation regions is commonly silicon dioxide, although other dielectric materials can also be used such as undoped polysilicon, silicon nitride, silicon oxynitride, fluoride-doped silicate glass, or another high-k or low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 102, then recessed back down to the desired height.

Next, as indicated in step 304 of FIG. 2A and as illustrated in FIG. 3, a first mask 191 is applied to the base substrate 100. This may be done, for example, by applying a layer of photoresist or a dielectric material (i.e. hard mask) and patterning the layer. Then, in step 306 of FIG. 2A and as illustrated in FIG. 4, a first trench 200 is formed in the first SOI region 110. This may be done by etching.

As illustrated here, the first trench has a base or floor 202, a first sidewall 204, and a second sidewall 206. A tilt angle A of the trench sidewalls is shown here relative to the base/floor and measured within the trench. The tilt angle A may be, in some particular embodiments, 90° or greater, or up to 150°, though other ranges are within the scope of the present disclosure.

After the first mask is removed, as indicated in step 310 of FIG. 2A and as illustrated in FIG. 5, a second mask 192 is applied to the base substrate. As illustrated here, a greater portion of the upper surface 102 of the base substrate is exposed in the second mask compared to the first mask. The base/floor 202 and both sidewalls 204, 206 are also exposed.

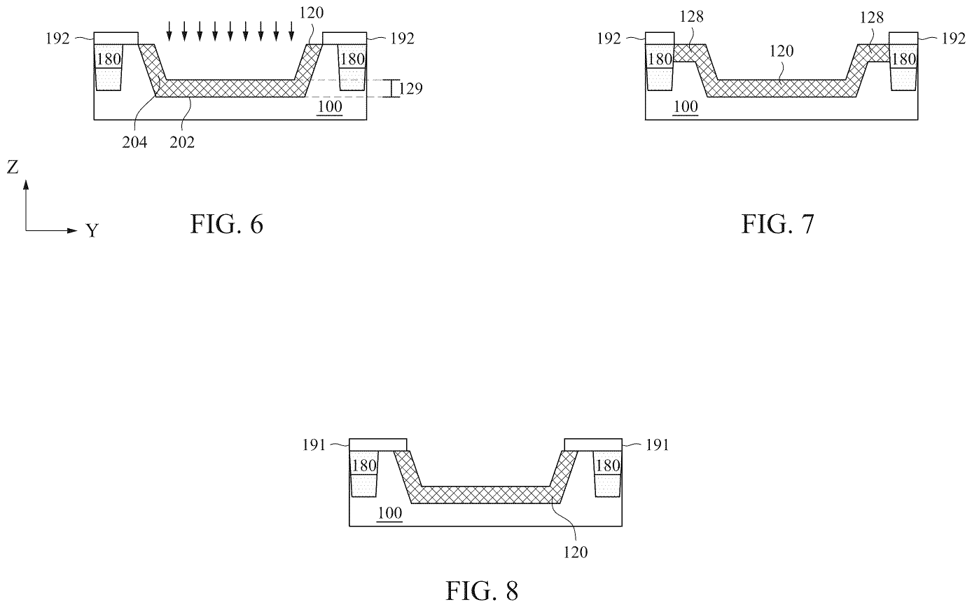

Then, in step 312 of FIG. 2A and as illustrated in FIG. 6, the base/floor 202 and at least one sidewall 204 of the first trench are doped with a first dopant type to form at least one first pickup channel 120. Put another way, a first dopant type is implanted in the base/floor 202 and at least one sidewall 204 of the first trench. Alternatively, the first pickup channel 120 is formed upon an upper surface of the trench. This may be performed by ion implantation.

The doping may be performed by ion implantation or other suitable methods. Briefly, in ion implantation, an ion implanter is used to implant atoms into a crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths. Alternatively, the substrate can be partially etched, followed by blanket deposition of the dopant, following by annealing in which the dopant reacts with the underlying exposed silicon.

Non-limiting examples of n-type dopants for silicon substrates may include nitrogen (N), phosphorus (P), arsenic (As), bismuth (Bi), or tantalum (Ta). Non-limiting examples of p-type dopants for silicon substrates may include boron (B), aluminum (Al), gallium (Ga), or indium (In). The resulting pickup channel may thus be considered a highly doped semiconductor material or a metal silicide, as appropriate.

In some embodiments, the dopant is implanted at a concentration of about 1×10¹⁵ cm⁻² or greater, such as from about 1×10¹⁵ to about 1×10¹⁸ cm⁻². In particular embodiments, the dopant may be implanted at an energy of about 20 keV to about 100 keV. Other ranges for each of these settings fall within the scope of this disclosure. Any suitable implant angle may be used. In particular embodiments, the first pickup channel 120 may have a height or depth 129 of about 10 nanometers (nm) to about 100 nm. However, other ranges and values are within the scope of the present disclosure.

It is noted that FIG. 6 does not include the optional contact regions 128 that are illustrated in FIG. 1A. In an alternative embodiment illustrated in FIG. 7, in step 314 the second mask 192 is patterned to expose more of the upper surface, such that contact regions 128 are also formed during this doping step.

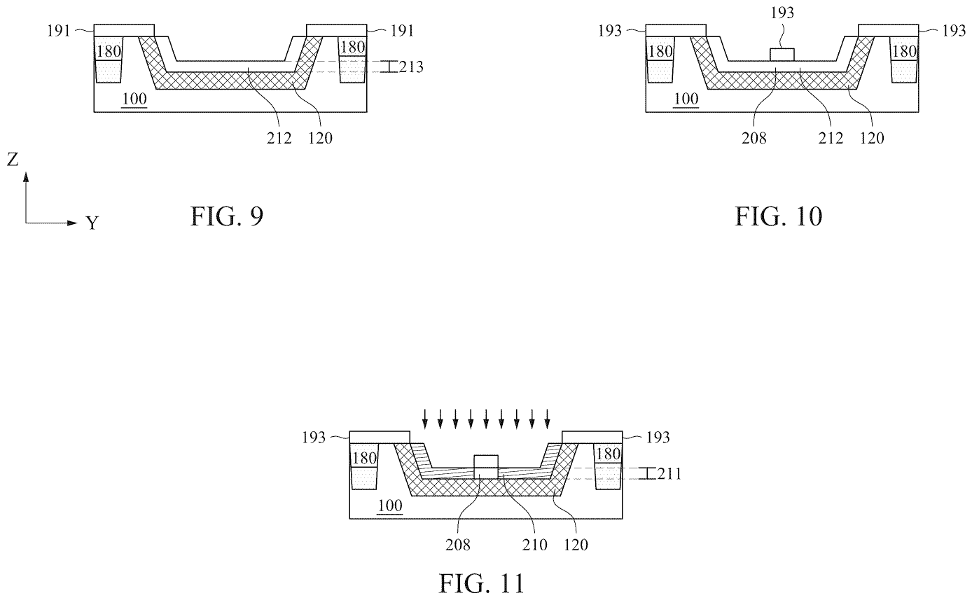

After the second mask is removed, as indicated in step 322 of FIG. 2A and as illustrated in FIG. 8, the first mask 191 is reapplied to the base substrate. Subsequently, in step 324 of FIG. 2A and as illustrated in FIG. 9, a first epitaxial layer 212 is formed in the first trench 200 over the first pickup channel 120. This may be done, for example, by chemical vapor deposition (CVD), physical vapor deposition (PVD), molecular beam epitaxy (MBE), or other suitable methods. The crystalline orientation of the first epitaxial layer will match that of the base substrate. In particular embodiments, the height or depth 213 of the first epitaxial layer may be from about 30 nanometers (nm) to about 300 nm. However, other ranges and values are within the scope of the present disclosure. The first epitaxial layer may now be considered to form the upper surface of the first trench 200.

Continuing, the first mask is removed again and as indicated in step 326 of FIG. 2A and as illustrated in FIG. 10, a third mask 193 is applied to the base substrate. The third mask covers one or more central regions 208 of the first trench, which will eventually form the central layer(s) of the first pickup channel.

Next, in step 328 of FIG. 2A and as illustrated in FIG. 11, a layer of or within the first trench (the exposed portion) is doped with a primary dopant to form a primary dopant-doped layer 210. This may be performed by ion implantation. In particular embodiments, the primary dopant is oxygen or nitrogen. The central region 208 is not doped by the primary dopant. In particular embodiments, the height or depth 211 of the primary dopant-doped layer may be from about 30 nanometers (nm) to about 300 nm. However, other ranges and values are within the scope of the present disclosure.

In some embodiments, the primary dopant is implanted at a concentration of about 1×10¹⁵ cm⁻² or greater, such as from about 1×10¹⁵ to about 1×10¹⁹ cm⁻² or from about 5×10¹⁵ to about 5×10¹⁸ cm⁻². In particular embodiments, the dopant may be implanted at an energy of about 50 keV to about 300 keV. Other ranges for each of these settings fall within the scope of this disclosure. Any suitable implant angle may be used.

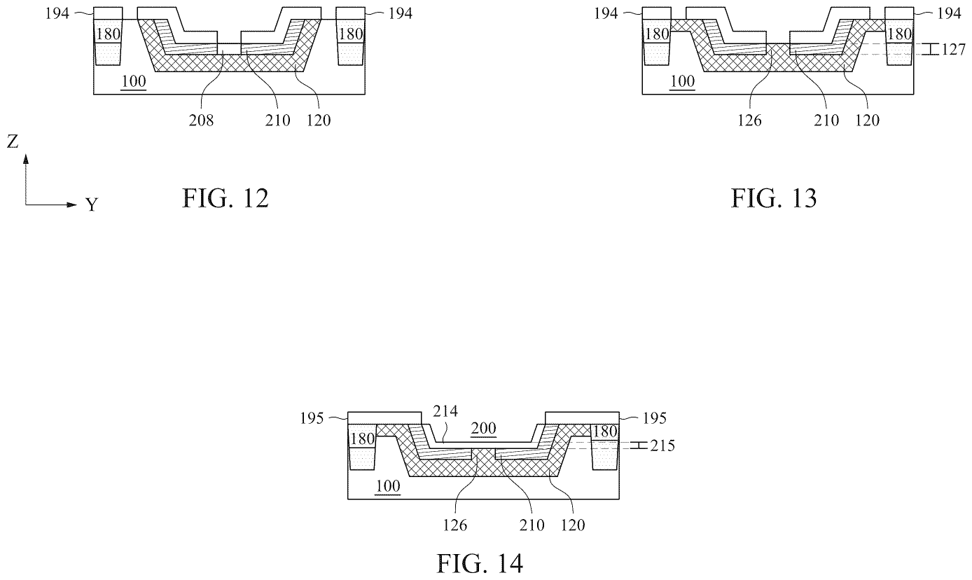

Continuing, the third mask is removed and as indicated in step 330 of FIG. 2A and as illustrated in FIG. 12, a fourth mask 194 is applied to the base substrate. The fourth mask exposes the one or more central regions 208 of the first trench. The fourth mask also covers the primary dopant-doped layer 210 in the first trench. It is noted that as illustrated here, the fourth mask is patterned to expose parts of the upper surface 102, such that contact regions could also be formed during this doping step if desired.

Then, in step 332 of FIG. 2A and as illustrated in FIG. 13, the central region 208 is doped with the first dopant type to form at least one central layer 126 of the first pickup channel 120. Again, this may be performed by ion implantation. The doping to form contact regions here is indicated as step 334.

In some embodiments, the dopant is implanted at a concentration of about 1×10¹⁵ cm⁻² or greater, such as from about 1×10¹⁵ to about 1×10¹⁸ cm⁻². In particular embodiments, the dopant may be implanted at an energy of about 20 keV to about 100 keV. Other ranges for each of these settings fall within the scope of this disclosure. Any suitable implant angle may be used. In particular embodiments, the central layer 126 may have a height or depth 127 of about 30 nanometers (nm) to about 300 nm, or in other words the central layer extends through the primary dopant-doped layer 210. However, other ranges and values are within the scope of the present disclosure.

Continuing, the fourth mask is removed and as indicated in step 346 of FIG. 2B and as illustrated in FIG. 14, a fifth mask 195 is applied to the base substrate. The fifth mask covers the upper surface of the base substrate 100 and exposes the first trench 200.

Subsequently, in step 348 of FIG. 2B, a second epitaxial layer 214 is formed in the first trench 200 over the primary dopant-doped layer 210. This may be done as previously described. The crystalline orientation of the second epitaxial layer will match that of the base substrate. In particular embodiments, the height or depth 215 of the second epitaxial layer may be from about 10 nanometers (nm) to about 300 nm. However, other ranges and values are within the scope of the present disclosure. The second epitaxial layer may now be considered to form the upper surface of the first trench 200.

It is noted that in some embodiments, the doping to form the first pickup channel (step 312) and the doping to form the primary dopant-doped layer (step 328) may be performed at sufficient depth within the base substrate 100 that there is no need to form the first epitaxial layer 212 and the second epitaxial layer 214. Thus, steps 322, 324, 346, and 348 are indicated as being optional in FIG. 2A and FIG. 2B.

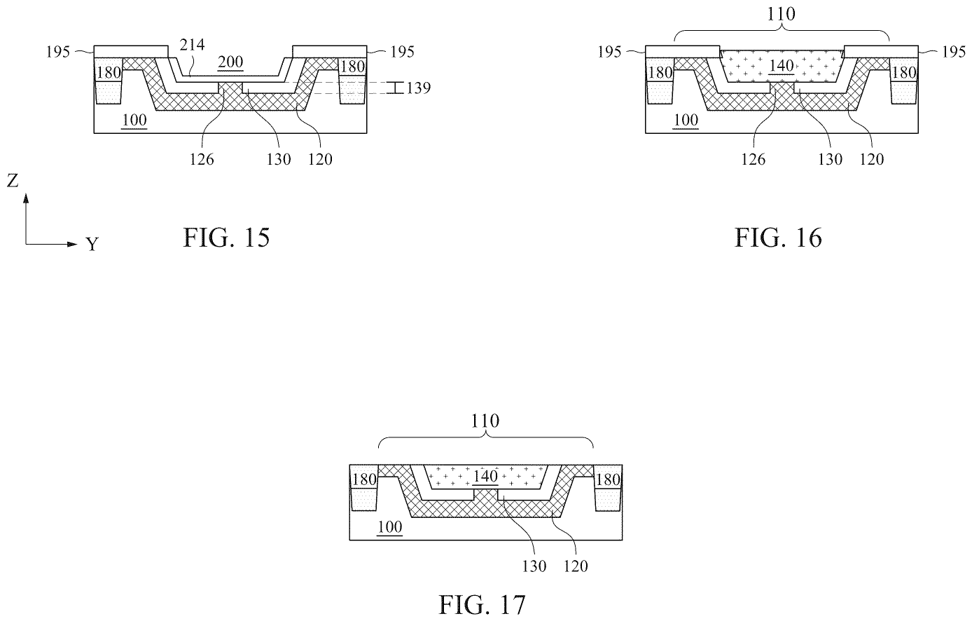

Then, as indicated in step 350 of FIG. 2B and as illustrated in FIG. 15, a first buried dielectric layer 130 is formed from the primary dopant-doped layer. This may be done, for example, by annealing, so that the primary dopant may react with the other material in the layer. In some embodiments, the thermal annealing is performed at a temperature from about 900° C. to about 1000° C. The thermal annealing may be performed for a time of about 10 seconds to about 100 minutes. Other temperature and time ranges are also within the scope of this disclosure. It is noted that the fifth mask 195 is thus usually a hard mask.

The first buried dielectric layer may be made of any suitable electrically insulating material. For example, in particular embodiments, the buried dielectric layer is formed from an oxide, such as silicon dioxide, and may be known as a buried oxide layer or BOX layer. However, the buried dielectric layer could also be formed from a nitride, such as silicon nitride. In particular embodiments, the height or depth 139 of the buried dielectric layer may be from about 10 nanometers (nm) to about 300 nm. However, other ranges and values are within the scope of the present disclosure.

Subsequently, in step 354 of FIG. 2B and as illustrated in FIG. 16, the first trench is filled to form a first semiconducting substrate 140. This may be done by epitaxy (i.e. a third epitaxial layer) or other suitable deposition process. In this regard, it is noted that the annealing used to form the first buried dielectric layer 130 works more uniformly through a relatively thin layer than a relatively thick layer. As a result, the first SOI region 110 is completed. It is noted that the central layer 126 electrically connects the first pickup channel 120 to the first semiconducting substrate 140. In addition, the first semiconducting substrate 140 may be made from a different material than the base substrate 100. For example, the base substrate may be silicon, while the first semiconducting substrate is SiGe or SiC.

If desired, in optional step 358 of FIG. 2B and as illustrated in FIG. 17, planarization may be performed to obtain a level surface. This may be done, for example, by chemical mechanical polishing (CMP), where the surface of a wafer is leveled using relative motion between the wafer and a rotating polishing pad to which a slurry is applied. Downward pressure is applied to push the wafer against the polishing pad, and elevated elements are worn down to obtain a surface with low surface roughness.

Next, in step 360 of FIG. 2B, a sixth mask is applied that exposes the first semiconducting substrate 140. Then, in step 362 of FIG. 2B, the first semiconducting substrate 140 is doped with the first dopant type. The resulting structure, a bias-controlled SOI region, is best illustrated in FIG. 1C.

Referring back to FIG. 1A, the second bias-controlled SOI region 112 can be formed after the first SOI region 110, or can be formed concurrently such that some common processing steps are performed in both SOI regions. Such steps are also indicated in FIG. 2A and FIG. 2B.

In step 308 of FIG. 2A, a second trench may be formed in a second SOI region of the base substrate. The first SOI region and the second SOI region are electrically isolated by the one or more isolation regions 180. The first mask 191 may be patterned appropriately so that a separate mask is not needed for this trench formation step. Next, in step 316, another mask may be applied so that in step 318, a second pickup channel 150 may be formed by doping a base/floor and at least one sidewall of the second trench with a second dopant type. In this regard, the implantation depths for the two dopant types are designed to be the same. However, their energy levels will depend on their size and atomic weight, and thus may vary. Optional step 320 indicates the formation of contact region(s) to the second pickup channel. If a first epitaxial layer is desired in the second trench, this may be formed in step 324 of FIG. 2A concurrently with the formation of the first epitaxial layer in the first trench.

Next, in step 336 of FIG. 2B, a mask is applied to cover one or more central regions of the second trench. Then, in step 338 of FIG. 2B, a layer of or within the second trench is doped with a secondary dopant around one or more central regions of the second trench. If the primary dopant and the secondary dopant are the same, the third mask 193 of step 326 may be patterned appropriately so that a separate mask is not needed for this step. Alternatively, if the second SOI region is to have a different structure or if the secondary dopant is different, step 336 indicates a different mask is applied for the second SOI region.

Continuing, as indicated in step 340 of FIG. 2B, a mask is applied to the base substrate that exposes the one or more central regions of the second trench. Next, in step 342 of FIG. 2B, the one or more central regions of the second trench are doped with the second dopant type to form one or more central layers electrically connected to the second pickup channel. The contact regions could alternatively be formed now as well, as indicated by step 344.

If a second epitaxial layer is desired in the second trench, this may be formed in step 348 of FIG. 2B concurrently with the formation of the second epitaxial layer in the first trench. Then, in step 352 of FIG. 2B, a second buried dielectric layer 160 is formed from the secondary dopant-doped layer of the second trench. Steps 350 and 352 are generally performed at the same time.

Continuing, in step 356 of FIG. 2B, the second trench is filled to form the second semiconducting substrate 170 above the second buried dielectric layer 160. Steps 354 and 356 are generally performed at the same time.

Next, in step 364 of FIG. 2B, a mask is applied that exposes the second semiconducting substrate 170. Then, in step 366 of FIG. 2B, the second semiconducting substrate 170 is doped with the second dopant type. The resulting structure is best illustrated in FIG. 1A.

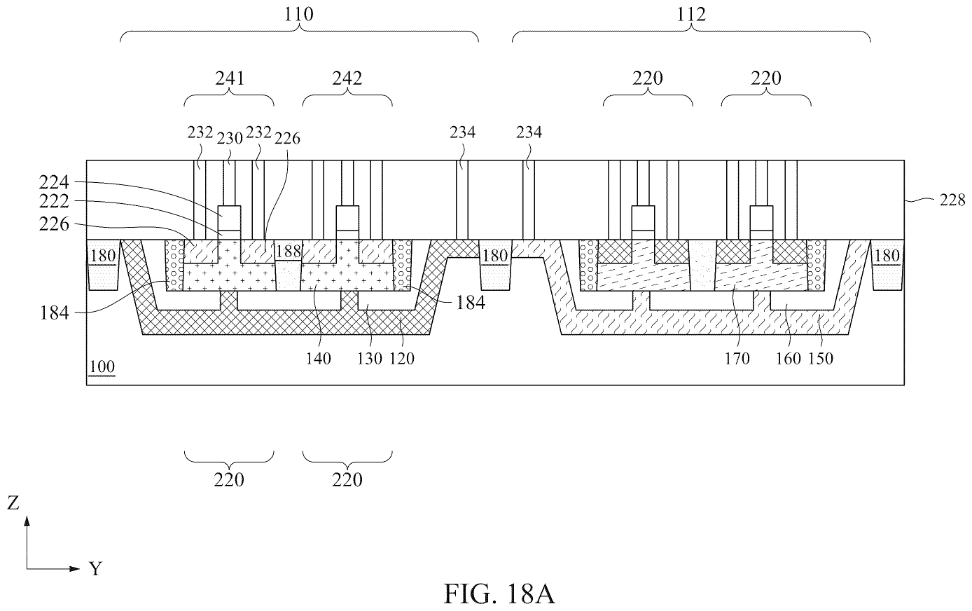

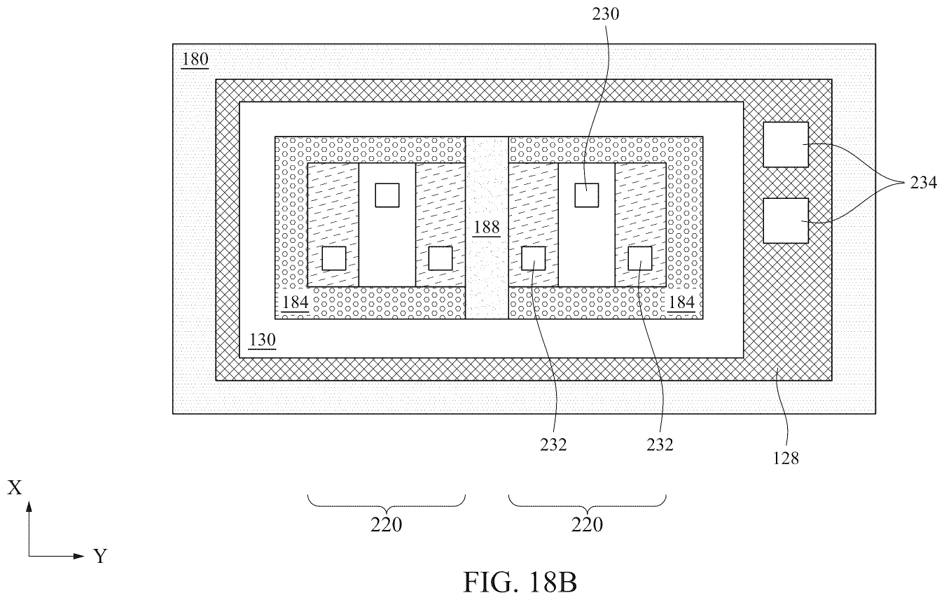

Continuing, in step 368 of FIG. 2B and with reference to FIG. 18A, one or more integrated circuits are formed in the first semiconducting substrate 140 and/or the second semiconducting substrate 170. Next, in step 370, an interlayer dielectric (ILD) layer 228 can be formed over the semiconducting substrates. Then, in step 372, electrical contacts 234 are formed to at least the two pickup channels 120, 150. This may be done by forming vias, and then filling the vias with an electrically conductive material. The resulting structure is illustrated in FIG. 18A, which provides a Y-axis cross-sectional view. FIG. 18B provides a plan view of the first SOI region 110 of FIG. 18A.

To build integrated circuits, photolithographic patterning processes use ultraviolet light to transfer a desired mask pattern to photoresist. Etching processes may then be used to transfer to the pattern to a layer below the photoresist. This process is repeated multiple times with different patterns of electrically conductive materials and electrically insulating materials to build different conductive, resistive, and/or insulating layers on the wafer substrate. Suitable examples of integrated circuit components may include, for example and without limitation, active components (e.g., transistors), passive components (e.g., capacitors, inductors, resistors, and the like), or combinations thereof.

As illustrated in FIG. 18A, planar transistors 220 are present in the first SOI region 110 and the second SOI region 112. The first SOI region 110 is divided into two active regions 241, 242, with a transistor in each active region. As illustrated, the planar transistor 220 includes a gate dielectric layer 222 which is present upon the first semiconducting substrate 140. A gate electrode 224 is located upon the gate dielectric layer 222. Two source/drain (S/D) electrodes 226 are formed in the first semiconducting substrate 140 by doping with the second dopant type. The gate electrode 224 is located between the two source/drain (S/D) electrodes 226. An interlayer dielectric (ILD) layer 228 covers the base substrate 100, including the first SOI region 110 and the second SOI region 112. Electrical contacts 230, 232, 234 are formed to the gate electrode 224, the S/D electrodes 226, and to the first pickup channel 120. An inner isolation region 188 is illustrated as separating the two planar transistors 220 in the first SOI region. An optional outer isolation region 184 is also illustrated between the transistors 220 and the first buried dielectric layer 130. The second SOI region has a similar structure.

Referring to the plan view of FIG. 18B, it can be seen that the outer isolation region 184 surrounds the two transistors 220 on three sides, with the inner isolation region 188 forming a fourth side around the two transistors. The contact region 128 of the first pickup channel is relatively thin on three sides, and is wider on the fourth side where two electrical contacts 234 are made to the first pickup channel 120. As shown here, the gate electrical contacts 230 may be staggered relative to the S/D electrical contacts 232. It should be noted that the various isolation regions 180, 184, 188 and the buried dielectric layer 130 can be the same material.

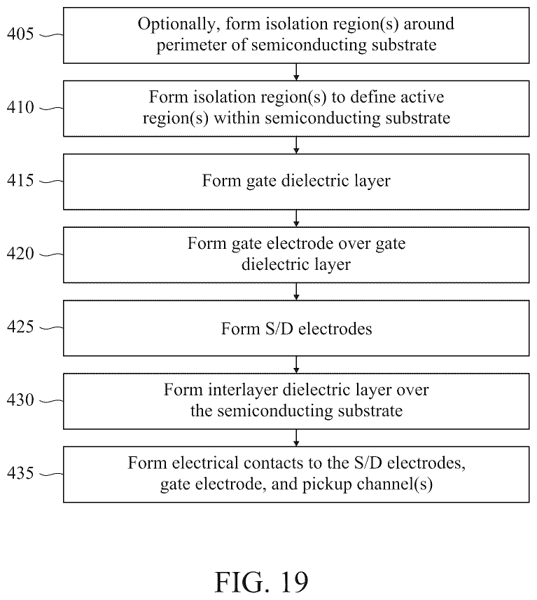

FIG. 19 is a flow chart illustrating a method 400 for forming a semiconducting device in an SOI region, in accordance with some embodiments. The method is discussed with reference to FIG. 18A and FIG. 18B. While the method steps are discussed below in terms of forming a single device in a single SOI region, such discussion should also be broadly construed as applying to the concurrent formation of multiple devices in a single SOI region or multiple SOI regions. The method also describes formation of a planar transistor or an LDMOS transistor, but can be suitably adapted to form other devices. Other structures may also be concurrently formed. It is noted that not all steps described in the flow chart are required.

The method begins with optional step 405 of FIG. 19, where one or more isolation regions 184 are formed around the perimeter of the semiconducting substrate 140. Then, in step 410, one or more isolation regions 186 are formed to define one or more active regions 241, 242 of the semiconducting substrate 140. Next, in step 415, a gate dielectric layer 222 is formed upon the semiconducting substrate 140. Again, CVD, PVD, atomic layer deposition (ALD), ion implantation, or other suitable deposition process may be used to form the gate dielectric layer. The gate dielectric layer 222 is formed between the isolation regions 184, 186. Afterwards, in step 420, a gate electrode 224 is formed upon the gate dielectric layer 222. This may be done by CVD, PVD, or other suitable process. If desired, a gate spacer (not shown) may be formed upon the sidewalls of the gate electrode 224. Then, in step 425, source/drain (S/D) electrodes 226 are formed on opposite sides of the gate electrode 224. They may be formed using ion implantation or other suitable methods to dope the semiconducting substrate, or by patterning and deposition of suitable metals. Next, in step 430 of FIG. 19, an interlayer dielectric (ILD) layer 228 is formed over the substrate. Then, in step 435, electrical contacts 230, 232, 234 are formed to the gate electrode 224, the two S/D electrodes 226, and the pickup channels 120, 150. This may be done by forming vias, and then filling the vias with an electrically conductive material.

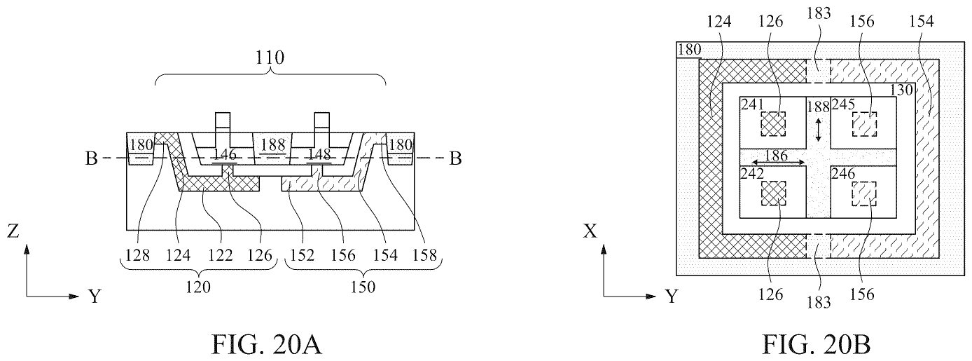

FIG. 20A and FIG. 20B are various views of another embodiment of a bias-controlled SOI region 110, according to some embodiments of the present disclosure. FIG. 20A is a Y-axis cross-sectional view. FIG. 20B is a plan view through line B-B of FIG. 20A. In this embodiment, the SOI region includes at least one n-type pickup channel and at least one p-type pickup channel.

As seen in FIG. 20A, the SOI region 110 includes an n-type pickup channel 120 formed from a bottom layer 122, at least one sidewall 124, and at least one central layer 126, and optionally at least one contact region 128. Similarly, a p-type pickup channel 150 is formed from a bottom layer 152, at least one sidewall 154, and at least one central layer 156, and optionally at least one contact region 158. A buried dielectric layer 130 is present above the pickup channels 120, 150 and below the semiconducting substrate 140. The semiconducting substrate 140 is split into an n-doped well 146 and a p-doped well 148.

As seen in FIG. 20B, the semiconducting substrate is divided into four active regions 241, 242, 245, 246 by one isolation region 188 running along the X-axis and one isolation region 186 running along the Y-axis. The active regions are organized in a 2×2 array, with two n-doped active regions 241, 242 on the left-hand side and two p-doped active regions 245, 246 on the right-hand side. In this view, the central layers 126, 156 are also shown. The n-type pickup channel 120 and the p-type pickup channel 150 are each illustrated as having sidewalls 124, 154 with three sides. It is noted that the isolation areas 183 between the n-type pickup channel 120 and the p-type pickup channel 150 outside the buried dielectric layer may be formed when isolation region 180 is formed or when isolation region 188 is formed. It is noted that here, the two n-doped active regions 241, 242 have the same electrical potential, and so they can share the same central layer and n-type pickup channel. Put another way, the ratio of active regions to pickup channels does not have to be 1:1, and may be higher if desired.

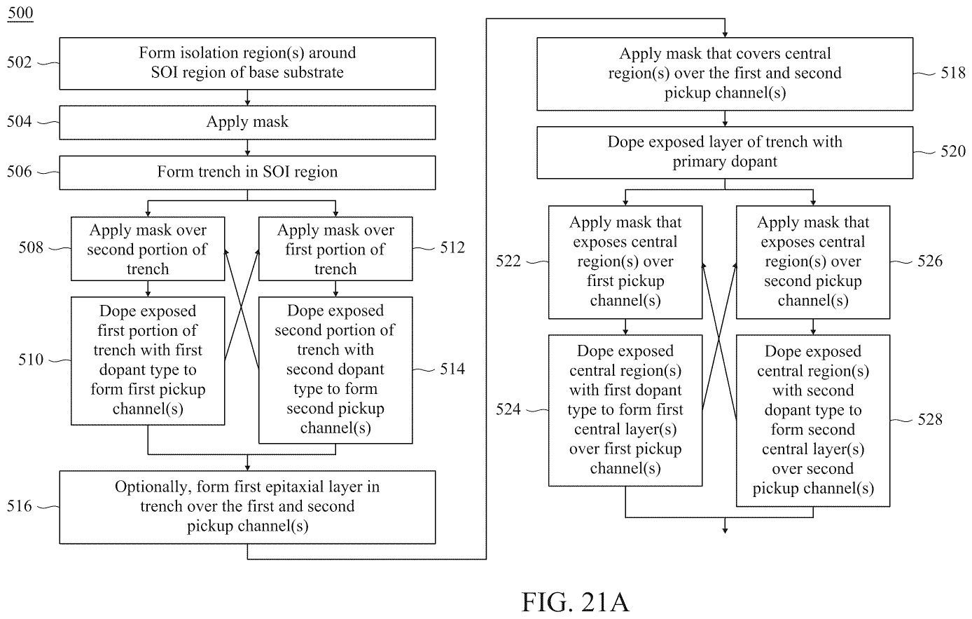

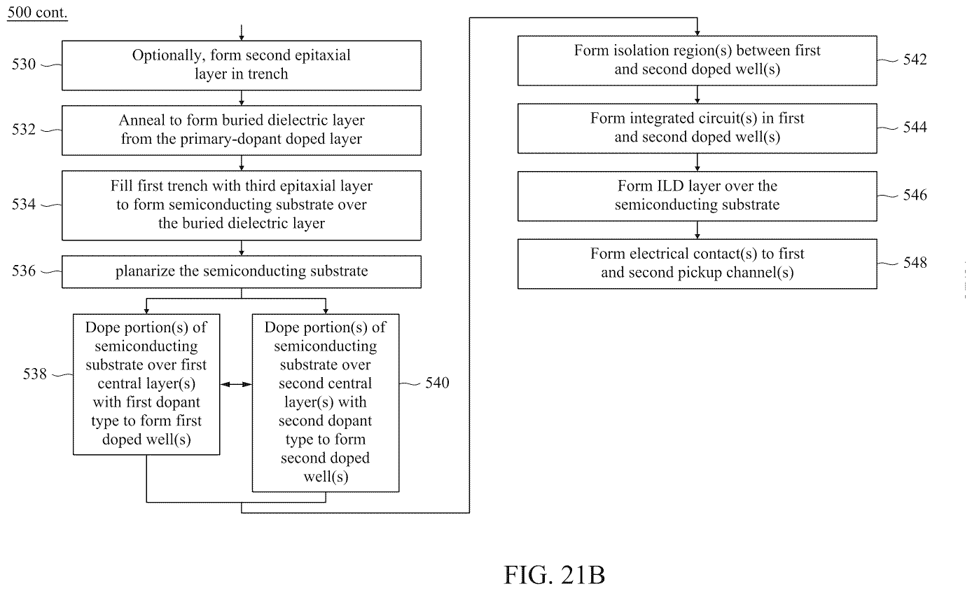

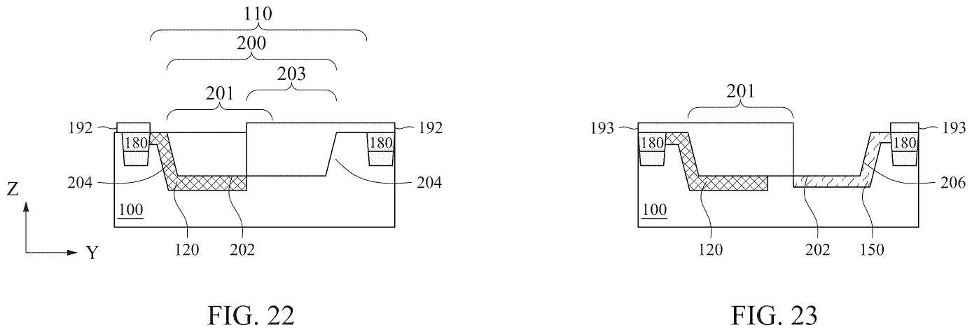

FIG. 21A and FIG. 21B together form a flow chart illustrating a method 500 for forming an SOI region in a base substrate, in accordance with some embodiments. Some steps of the method are also illustrated in FIGS. 22-32. These figures provide different views for better understanding. It is noted that in these figures, only Y-axis cross-sectional views are illustrated, and it may be assumed that the X-axis cross-sectional views are similar to the Y-axis views. While the method steps are discussed below in terms of forming an n-type pickup channel and a p-type pickup channel in a single SOI region, such discussion should also be broadly construed as applying to the formation of multiple pickup channels in a single SOI region, or the concurrent formation of multiple SOI regions. Other structures may also be concurrently formed. It is noted that not all steps described in the flow chart are required, and not all method steps are described in the flow chart.

Initially, as indicated in step 502 of FIG. 21A and as illustrated in FIG. 22, one or more isolation region(s) 180 are formed within the base substrate 100 to define the SOI region 110. Next, in step 504 of FIG. 21A, a first mask (not shown) is applied to the base substrate 100. Then, in step 506 of FIG. 21A, a trench 200 is formed in the SOI region 110, for example by etching. The trench may be divided into a first portion 201 and a second portion 203, which overlap each other. After the first mask is removed, in step 508 of FIG. 21A, a second mask 192 is applied that covers the second portion 203. Then, in step 510 of FIG. 21A, the exposed base/floor 202 and at least one sidewall 204 in the first portion of the trench are doped with a first dopant type to form at least one first pickup channel 120. The resulting structure is shown in FIG. 22.

Referring now to FIG. 23, after the second mask is removed, in step 512 of FIG. 21A, a third mask 193 is applied that covers the first portion 201 of the trench. Then, in step 514 of FIG. 21A, the exposed base/floor 202 and at least one sidewall 206 in the second portion of the trench are doped with a second dopant type to form at least one second pickup channel 150. The resulting structure is shown in FIG. 23. It should be noted the first pickup channel 120 and the second pickup channel 150 do not contact each other. In addition, the first pickup channel 120 and the second pickup channel 150 can be formed in either order, as indicated in FIG. 21A.

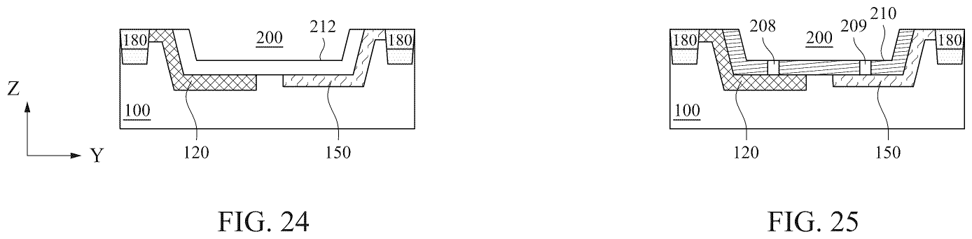

Next, as indicated in step 516 of FIG. 21A and as illustrated in FIG. 24, a fourth mask (not shown) can be applied, and a first epitaxial layer 212 may then be formed in the trench 200 over the first pickup channel 120 and the second pickup channel 150. This is done as previously described. The fourth mask is then removed. The first epitaxial layer may now be considered to form the upper surface of the trench.

Continuing, in step 518 of FIG. 21A, a fifth mask (not shown) is applied which covers one or more central regions 208, 209 over each pickup channel 120, 150. Then, in step 520 of FIG. 21A and as illustrated in FIG. 25, a layer of the trench (the exposed portion) is doped with a primary dopant to form a primary dopant-doped layer 210. The central regions 208, 209 are not doped by the primary dopant. The fifth mask is then removed.

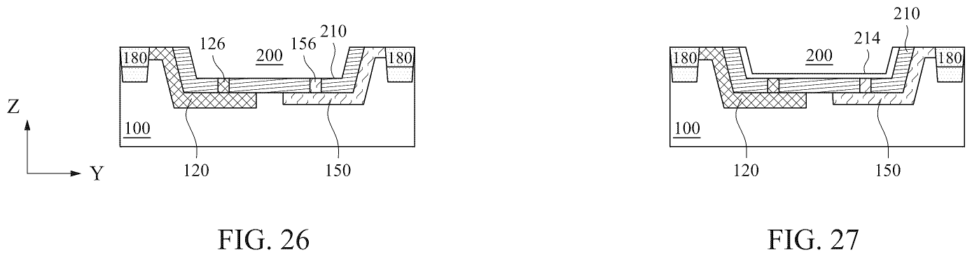

Next, in step 522 of FIG. 21A and with reference to FIG. 26, a sixth mask (not shown) is applied to the base substrate that exposes the central region 208 over the first pickup channel 120. The sixth mask also covers the primary dopant-doped layer 210 and the central region 208 over the second pickup channel 150. Then, in step 524 of FIG. 21A, the central region 208 is doped with the first dopant type to form at least one central layer 126 of the first pickup channel 120. This may be performed by ion implantation.

Then, in step 526 of FIG. 21A and with reference to FIG. 26, a seventh mask (not shown) is applied to the base substrate that exposes the central region 208 over the second pickup channel 150. The seventh mask also covers the primary dopant-doped layer 210 and the central layer 126 over the first pickup channel 120. Then, in step 528 of FIG. 21A, the central region 208 is doped with the second dopant type to form at least one central layer 156 of the second pickup channel 150. This may be performed by ion implantation. The resulting structure is shown in FIG. 26. It is noted the first central layer 126 and the second central layer 156 can be formed in either order, as indicated in FIG. 21A.

Next, as indicated in step 530 of FIG. 21B and as illustrated in FIG. 27, an eighth mask (not shown) can be applied, and a second epitaxial layer 214 may then be formed in the trench 200 over the primary dopant-doped layer 210. This is done as previously described. The eighth mask is then removed. The second epitaxial layer may now be considered to form the upper surface of the trench.

It is noted that in some embodiments, the doping to form the pickup channels (steps 508-514) and the doping to form the primary dopant-doped layer (step 520) may be performed at sufficient depth within the base substrate 100 that there is no need to form the first epitaxial layer 212 or the second epitaxial layer 214. Thus, steps 516 and 530 are indicated as being optional in FIG. 21A and FIG. 21B.

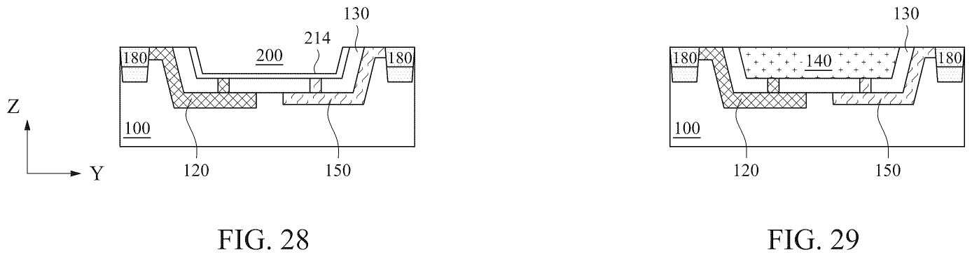

Then, as indicated in step 532 of FIG. 21B and as illustrated in FIG. 28, a buried dielectric layer 130 is formed from the primary dopant-doped layer. This may be done, for example, by annealing. Again, then, the eighth mask is usually a hard mask. Subsequently, in step 534 of FIG. 21B and as illustrated in FIG. 29, the trench is filled (i.e. with a third epitaxial layer) to form a semiconducting substrate 140. If desired, planarization may be performed in step 536 to obtain a level surface.

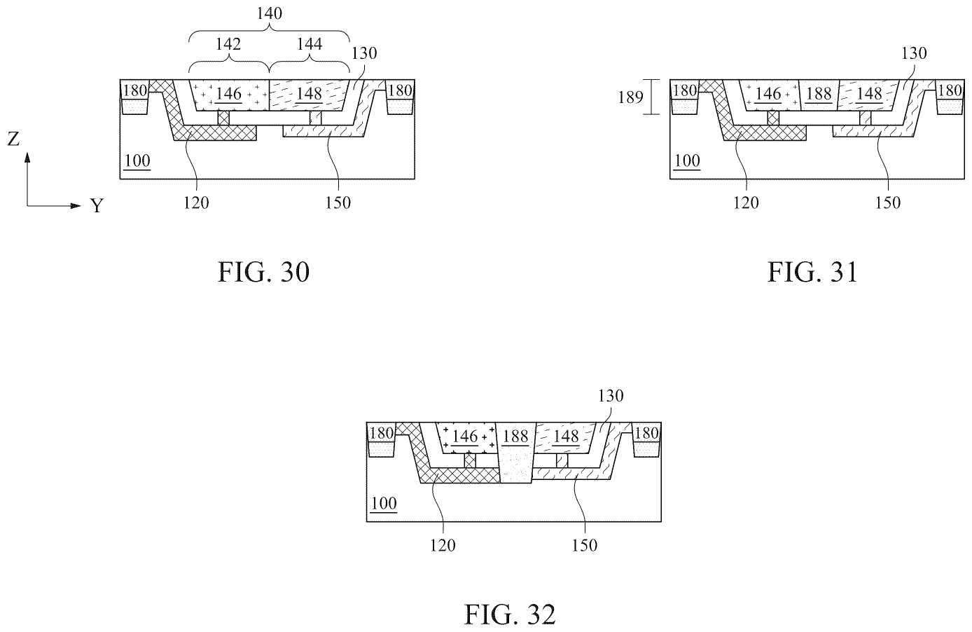

Referring to FIG. 30, the semiconducting substrate 140 may be divided into one or more first portions 142 and second portions 144, which do not overlap each other. In step 538 of FIG. 21B, the first portion 142 over the first pickup channel 120 is doped with the first dopant type to form a first doped well 146. In step 540 of FIG. 21B, the second portion 144 over the second pickup channel 150 is doped with the second dopant type to form a second doped well 148. The first and second doped wells 146, 148 can be formed in either order, as indicated in FIG. 21B.

Next, in step 542 of FIG. 21B and as illustrated in FIG. 31, one or more isolation regions 188 are formed between the first and second doped wells 146, 148. Referring back to FIG. 20B, isolation region 186 would also be formed in this step. two or more different active regions can be formed depending on how many isolation regions 186, 188 are made. In FIG. 31, the isolation region 188 has a depth 189 which extends through the semiconducting substrate and does not extend into the buried dielectric layer 130. However, as illustrated in FIG. 32, the isolation region 188 may extend into the buried dielectric layer 130, and can also extend into the base substrate 100. This can also ensure the first pickup channel 120 and the second pickup channel 150 are electrically isolated from each other. Continuing, as discussed in step 544 of FIG. 21B, integrated circuits can be formed in the first and second doped wells 146, 148. This may be done as described in FIG. 19. In step 546, an ILD layer is formed over the semiconducting substrate (see FIG. 18A). In step 548 of FIG. 21B, electrical contacts can be formed to the first and second pickup channels 120, 150 (see FIG. 18A).

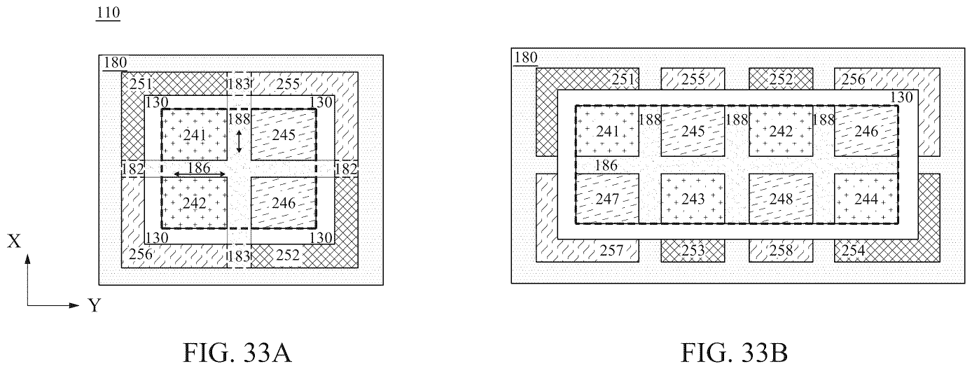

FIG. 33A is another embodiment of an SOI region 110. Here, four active regions are organized in a 2×2 array. Two n-doped active regions 241, 242 are located at the top left side and the bottom right side, along with two n-doped contact regions 251, 252 of two different n-type pickup channels. Two p-doped active regions 245, 246 are located at the top right side and the bottom left side, along with two p-doped contact regions 255, 256 of two different p-type pickup channels.

Each contact region 251, 252, 255, 256 has two sides. First n-doped contact region 251 controls the bias in active region 241. Second n-doped contact region 252 controls the bias in active region 242. First p-doped contact region 255 controls the bias in active region 245. Second p-doped contact region 256 controls the bias in active region 246.

The structure shown in FIG. 20B can also be compared to the structure shown in FIG. 33A. In FIG. 20B, the buried dielectric layer 130 around the active regions is one continuous sidewall. However, in FIG. 33A, the buried dielectric layer 130 is divided into four sections by the isolation regions 186, 188. This indicates that in FIG. 20B, the isolation areas 182, 183 between the n-type pickup channel 120 and the p-type pickup channel 150 outside the buried dielectric layer were formed when isolation region 180 was formed. In FIG. 33A, the isolation areas 182, 183 were formed when isolation regions 186, 188 were formed. This may also be done to remove any overlap between the n-type pickup channels and p-type pickup channels.

FIG. 33B is another embodiment of an SOI region 110. Here, eight active regions are organized in a 2×4 array. Four separate n-type pickup channels and four separate p-type pickup channels were formed in this embodiment. In the top row, two n-doped active regions 241, 242 alternate with two p-doped active regions 245, 246. An n-doped active region 241 is present on the far left. In the bottom row, two p-doped active regions 247, 248 alternate with two n-doped active regions 243, 244. A p-doped active region 247 is present on the far left.

The four contact regions 251, 254, 256, 257 at the corners have two sides. The four contact regions 252, 253, 255, 258 between the corners have one side. First n-doped contact region 251 controls the bias in active region 241. Second n-doped contact region 252 controls the bias in active region 242. Third n-doped contact region 253 controls the bias in active region 243. Fourth n-doped contact region 254 controls the bias in active region 244. First p-doped contact region 255 controls the bias in active region 245. Second p-doped contact region 256 controls the bias in active region 246. Third p-doped contact region 257 controls the bias in active region 247. Fourth p-doped contact region 258 controls the bias in active region 248.

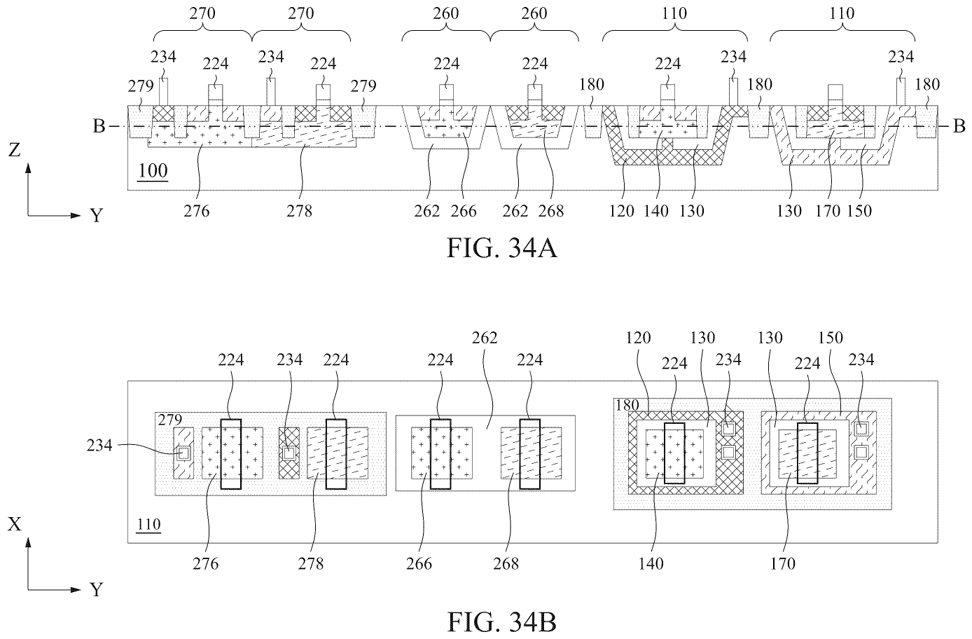

FIG. 34A is a Y-axis cross-sectional view of a base substrate 100 that includes integrated circuits in two active regions 270 of the base substrate, two non-bias-controlled SOI regions 260, and two bias-controlled SOI regions 110. FIG. 34B is a plan view through line B-B of FIG. 34A. Electrical contacts 234 for bias control are also shown. This is an illustration of the flexible layout structure permitted by the methods of the present disclosure. Gate electrodes 224 are indicated as well.

The active regions 270 do not include a buried dielectric layer or pickup channels. The non-bias-controlled SOI regions 260 include a buried dielectric layer 262 that separates the base substrate 100 from a doped semiconducting substrate 266, 268. No pickup channels are present in the non-bias-controlled SOI regions.

In forming the base substrate of FIG. 34A, the buried dielectric layer 262 of each non-bias-controlled SOI region 260 can be formed concurrently when the buried dielectric layer 130 of each bias-controlled SOI region 110 is formed. The n-doped wells 266, 276 and p-doped wells 268, 278 in each non-bias-controlled SOI region 260 and each active region 270 can be formed concurrently when the semiconducting substrates (140, 170) in each bias-controlled SOI region 110 are doped. Any isolation regions 279 in each non-bias-controlled SOI region 260 or active region 270 can be formed concurrently when the isolation region 180 is formed in each bias-controlled SOI region 110. Similarly, the integrated circuits in each non-bias-controlled SOI region 260 or active region 270 can be formed concurrently when they are formed in each bias-controlled SOI region 110.

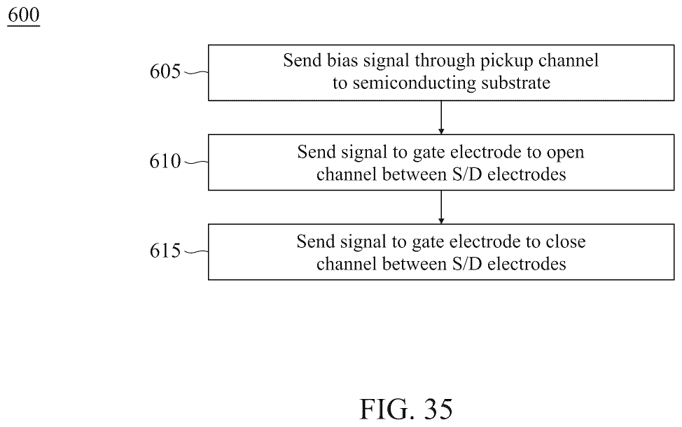

FIG. 35 is a flow chart illustrating a method 600 for operating a transistor in a bias-controlled SOI region, in accordance with some embodiments. The method steps are discussed below in terms of using a single transistor and a single SOI region, and should also be broadly construed as applying to the concurrent use of multiple transistors and/or multiple SOI regions. Reference is also made to the structure of FIG. 18A.

In step 605 of FIG. 35, a bias signal is sent through the first pickup channel 120 to the semiconducting substrate 140. This is typically a current or voltage signal, which changes the bias of the semiconducting substrate. In step 610, a signal is sent to the gate electrode 224. Typically, a voltage signal is sent to the gate electrode, either in the form of an increased voltage or a decreased voltage (depending on how the gate electrode is operated). This opens a channel (not illustrated) between the S/D electrodes 226, which permits current to flow between them. The bias signal aids in stabilizing the transistor so that the transistor performance varies very little when operating conditions change. In step 615 of FIG. 35, a different signal is sent to the gate electrode 224 to close the channel, causing current flow to end. The active regions 270 of FIG. 34A may be operated in the same manner. The non-bias-controlled SOI regions 260 do not receive a bias signal.

It is also noted that certain process steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

The base substrates may be incorporated into larger semiconductor packages and into larger devices. Such packages may also include various interconnect structures for communicating with other semiconductor devices. The semiconductor devices may be useful in amplifiers; power management devices; BCD (Bipolar-CMOS-DMOS) circuits for driving discrete high voltage components; image signal processors (ISP); LCD, OLED, AMOLED, or QLED display panels; image sensors that can be used in systems such as mobile telephones, facial recognition systems, or as motion sensors for automotive applications, security applications, energy efficiency, etc.

The substrates of the present disclosure having bias-controlled SOI regions have several advantages. Full electrical isolation provides better device performance and permits withstanding of higher voltage, which is useful for high-voltage applications. Parasitic capacitance is also reduced. The substrates can be completed using foundry in-house processes with current semiconductor process tools. There is no area loss due to the need for H-body contacts. The structures are flexible and permit different designs as needed. The structures are detectable. Separate high-priced SOI substrates do not need to be used, and bulk devices and SOI devices can be built on the same base substrate.

Some embodiments of the present disclosure thus relate to methods for making a base substrate with one or more SOI regions. A first trench is formed in a first SOI region of the base substrate. A base/floor and at least one sidewall of the first trench are doped with a first dopant type to form at least one pickup channel. A mask is applied to cover one or more central regions of the first trench. A layer within the first trench is doped with a primary dopant around the one or more central regions of the first trench. The mask is then removed. The one or more central regions of the first trench are then doped with the first dopant type to form one or more central layers electrically connected to the at least one pickup channel. A first buried dielectric layer is formed from the primary dopant-doped layer of the first trench. The first trench is then filled to form a first semiconducting substrate above the first buried dielectric layer. The one or more central layers are electrically connected to the first semiconducting substrate.

Other embodiments disclosed herein relate to a first bias-controlled SOI region of a base substrate. The first bias-controlled SOI region comprises a buried dielectric layer within the base substrate, a pickup channel, and a semiconducting substrate above the buried dielectric layer. The pickup channel comprises a bottom layer located below the buried dielectric layer and at least one sidewall extending upwards to an upper surface of the base substrate. One or more central layers extend through the buried dielectric layer and are electrically connected to the at least one pickup channel and to the semiconducting substrate.

Also described in various embodiments herein are methods for forming a base substrate with an SOI region that includes an n-doped pickup channel and a p-doped pickup channel. A trench is formed in an SOI region of the base substrate. A first dopant type is implanted in a bottom layer and at least one sidewall of the trench to form a first pickup channel. A second dopant type is implanted in the bottom layer and at least one sidewall of the trench to form a second pickup channel. A mask is applied that covers a first central region over the first pickup channel and a second central region over the second pickup channel. A primary dopant is implanted into a layer of the trench around the first central region and the second central region. The mask is removed. The first dopant type is implanted into the first central region to form a first central layer electrically connected to the first pickup channel. The second dopant type is implanted into the second central region to form a second central layer electrically connected to the second pickup channel. Annealing is performed to form a buried dielectric layer from the primary dopant-doped layer of the first trench. The first trench is filled to form a semiconducting substrate above the buried dielectric layer, wherein the first central layer and the second central layer are electrically connected to the semiconducting substrate. The semiconductor substrate above the first central layer is doped with the first dopant type to form a first doped well. The semiconductor substrate above the second central layer is doped with the second dopant type to form a second doped well. An isolation region is formed between the first doped well and the second doped well.

Methods for concurrently forming a bias-controlled SOI region and a non-bias controlled SOI region are also disclosed. Generally, a pickup channel is formed in the bias-controlled SOI region as described above. The non-bias-controlled SOI region includes a buried dielectric layer and a semiconducting substrate, which are formed in the base substrate concurrently with their formation in the bias-controlled SOI region. Integrated circuits may be concurrently formed in both regions. The resulting structures are also disclosed.

Methods for concurrently forming a bias-controlled SOI region and a doped active region in the base substrate are also disclosed. The bias-controlled SOI region is formed as described above. The active region is concurrently doped when the semiconducting substrate in the bias-controlled SOI region is doped. Isolation regions are also concurrently formed in the bias-controlled SOI region and the active region. Integrated circuits may be concurrently formed in both regions. The resulting structures are also disclosed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a first trench in a first silicon-on-insulator (SOI) region of a substrate;
doping a base and at least one sidewall of the first trench with a first dopant type to form at least one pickup channel;
doping a layer within the first trench with a primary dopant around one or more central regions of the first trench;
doping the one or more central regions of the first trench with the first dopant type to form one or more central layers electrically connected to the at least one pickup channel;
forming a first buried dielectric layer from the primary dopant-doped layer of the first trench; and
filling the first trench to form a first semiconducting substrate above the first buried dielectric layer, wherein the one or more central layers are electrically connected to the first semiconducting substrate.

2. The method of claim 1, wherein the at least one pickup channel is formed upon an upper surface of the first trench, and further comprising:
forming a first epitaxial layer in the first trench over the at least one pickup channel.

3. The method of claim 1, wherein oxygen is doped upon an upper surface of the first trench, and further comprising:
forming a second epitaxial layer in the first trench over the primary dopant-doped layer.

4. The method of claim 1, further comprising forming one or more contact regions of the at least one pickup channel by doping an upper surface of the substrate with the first dopant type.

5. The method of claim 4, wherein at least a first contact region and a second contact region are formed, and the first contact region has a different surface area from the second contact region.

6. The method of claim 1, wherein the at least one sidewall of the at least one pickup channel surrounds the first semiconducting substrate.

7. The method of claim 1, further comprising doping the first semiconducting substrate in the first SOI region with the first dopant type.

8. The method of claim 1, further comprising forming one or more electrical contacts to the at least one pickup channel.

9. The method of claim 1, wherein the at least one sidewall of the first trench has a tilt angle of 90° or greater.

10. The method of claim 1, wherein the substrate and the first semiconducting substrate are formed from different materials.

11. The method of claim 1, further comprising forming at least one transistor in the first semiconducting substrate.

12. The method of claim 1, further comprising forming one or more isolation regions around the first SOI region prior to forming the first trench.

13. The method of claim 12, further comprising:
forming a second trench in a second SOI region of the substrate, wherein the first SOI region and the second SOI region are electrically isolated by the one or more isolation regions;
doping a base and at least one sidewall of the second trench with a second dopant type to form at least one pickup channel, wherein the first dopant type and the second dopant type are different from each other;
doping a layer within the second trench with a secondary dopant around one or more central regions of the second trench;
doping the one or more central regions of the second trench with the second dopant type to form one or more central layers electrically connected to the at least one pickup channel;
forming a second buried dielectric layer from the secondary dopant-doped layer of the second trench; and
filling the second trench to form a second semiconducting substrate above the second buried dielectric layer, wherein the one or more central layers in the second trench are electrically connected to the second semiconducting substrate.

14. A structure, comprising:
a first bias-controlled SOI region of a substrate, the first bias-controlled SOI region comprising:
a buried dielectric layer within the substrate;
at least one pickup channel comprising a bottom layer located below the buried dielectric layer and at least one sidewall extending upwards to an upper surface of the substrate;
a semiconducting substrate above the buried dielectric layer; and
one or more central layers extending through the buried dielectric layer and electrically connected to the at least one pickup channel and to the semiconducting substrate.

15. The structure of claim 14, further comprising a second bias-controlled SOI region electrically isolated from the first bias-controlled SOI region, wherein the pickup channel and the semiconducting substrate of the first bias-controlled SOI region are doped with a first dopant type, and wherein the pickup channel and the semiconducting substrate of the second bias-controlled SOI region are doped with a second dopant type that is different from the first dopant type.

16. The structure of claim 15, wherein the pickup channel of the first bias-controlled SOI region has two sidewalls, and wherein the pickup channel of the second bias-controlled SOI region has one sidewall.

17. The structure of claim 14, further comprising an integrated circuit formed in an active region of the substrate.

18. The structure of claim 14, further comprising a non-bias-controlled SOI region of the substrate, the non-bias-controlled SOI region comprising a buried dielectric layer within the substrate that electrically isolates a semiconducting substrate from the substrate.

19. A method, comprising:
forming a trench in an SOI region of a base substrate;
implanting a first dopant type in a bottom layer and at least one sidewall of the trench to form a first pickup channel;
implanting a second dopant type in the bottom layer and at least one sidewall of the trench to form a second pickup channel;
implanting a primary dopant into a layer of the trench around a first central region over the first pickup channel and a second central region over the second pickup channel;
implanting the first dopant type into the first central region to form a first central layer electrically connected to the first pickup channel;
implanting the second dopant type into the second central region to form a second central layer electrically connected to the second pickup channel;
annealing to form a buried dielectric layer from the primary dopant-doped layer of the trench;
filling the trench to form a semiconducting substrate above the buried dielectric layer, wherein the first central layer and the second central layer are electrically connected to the semiconducting substrate;
doping the semiconductor substrate above the first central layer with the first dopant type to form a first doped well;
doping the semiconductor substrate above the second central layer with the second dopant type to form a second doped well; and
forming an isolation region between the first doped well and the second doped well.

20. The method of claim 19, further comprising forming at least one integrated circuit in the first doped well and at least one integrated circuit in the second doped well.
